(19) United States
(12) Patent Application Publication
(10) Pub. No.: US 2022/0037438 A1
(43) Pub. Date: Feb. 3, 2022

(54) SUBSTRATE, METHOD FOR MANUFACTURING SUBSTRATE, AND DISPLAY PANEL

(71) Applicants: Beihai HKC Optoelectronics Technology Co., Ltd., Beiha (CN); HKC Corporation Limited, Shenzhen (CN)

(72) Inventors: Renhong ZHAN, Beihai (CN); Chongwei TANG, Beihai (CN)

(21) Appl. No.: 17/343,787

(22) Filed: Jun. 10, 2021

(30) Foreign Application Priority Data
Jul. 30, 2020 (CN) 202010748390.6

(51) Int. Cl. H01L 27/32; H01L 51/56

(52) U.S. Cl. CPC H01L 27/3262; H01L 27/1222; H01L 2227/323; H01L 51/56

(57) ABSTRACT

Disclosed are a substrate, a method for manufacturing the substrate, and a display panel. The substrate includes a base, an active switch, an active light-emitting pixel array, and a reflective layer. The active switch is formed on the base. The reflective layer is formed on the base under the active switch and is disposed farther away from a light incident surface of the substrate than the active switch. The active light-emitting pixel array is coupled with the active switch. The active switch includes a polysilicon layer. The reflective layer totally covers the base and the reflective layer has a smooth surface.

The present application claims priority to the Chinese Patent Application No. CN202010748390.6, filed Jul. 30, 2020, which is hereby incorporated by reference herein as if set forth in its entirety.

### TECHNICAL FIELD

The present application relates to the field of display technologies, and in particular, to a substrate, a method for manufacturing the substrate, and a display panel.

### BACKGROUND

The statements herein are intended for mere purposes of providing background information related to the present application and do not necessarily constitute the conventional art.

With the development of flat-panel displays, there is continuous demand for panels with high resolution and low energy consumption. Amorphous silicon has low electron mobility. and In contrast, the low-temperature polysilicon can be manufactured at low temperatures and has relatively high electron mobility, so that it is widely researched to meet the requirements of high resolution and low energy consumption of panels. An amorphous silicon layer can be converted into a polysilicon layer by being irradiated by high-energy laser from a laser head.

However, the laser head requires frequent replacements due to its high energy characteristic, so there is a need to reduce the laser energy in order to lengthen the replacement cycle of the laser device consumables. This however will increase the time required for laser crystallization.

### SUMMARY

It is therefore one object of the present application to provide a substrate, a method of manufacturing the substrate, and a display panel that contribute to increasing the replacement cycle of the laser device consumables while reducing the time required for laser crystallization.

The application discloses a substrate including a base, an active switch, an active light-emitting pixel array, and a reflective layer. The active switch is formed on the base. The reflective layer is formed on the base under the active switch and is disposed farther away from the light incident surface of the substrate compared with the active switch. The active light-emitting pixel array is coupled with the active switch. The active switch includes a polysilicon layer. The reflective layer totally covers the base and has a smooth surface.

Optionally, the active switch includes a first cushion layer disposed on the base, and the polysilicon layer is disposed on the first cushion layer.

Optionally, the reflective layer and the active switch are respectively disposed on two sides of the base, and the base includes a protective layer that is disposed on and cladded to the reflective layer.

Optionally, the reflective layer and the active switch are disposed on the same side of the base, where the active switch includes a first cushion layer disposed on the reflective layer, and the polysilicon layer is disposed on the first cushion layer.

Optionally, the active switch includes a conductive layer, a second cushion layer, a first metal layer, a first insulating layer, a second metal layer, a second insulating layer, and a third metal layer. The substrate includes a third insulating layer covering the third metal layer, a flattening layer, and a transparent conductive film. The second cushion layer, the first metal layer, the first insulating layer, the second metal layer, the second insulating layer, the third metal layer, the third insulating layer, the flattening layer and the transparent conductive film are sequentially laid on the polysilicon layer. The third metal layer is coupled with the conductive layer through a first via hole, and the transparent conductive film is coupled with the third metal layer through a second via hole. The transparent conductive film covers the active switch and the active light-emitting pixel array in a direction perpendicular to the base.

Optionally, the reflective layer is made of aluminum.

This application further discloses a method for manufacturing a substrate, the method including:

forming a reflective layer and a first cushion layer on a base;

providing an amorphous silicon layer on the first cushion layer for an active switch and an active light-emitting pixel array; and

converting the amorphous silicon layer into a polysilicon layer by laser;

where the reflective layer is formed on the base under the active switch and is disposed farther away from the light incident surface of the substrate compared with the active switch; the reflective layer totally covers the base, the reflective layer has a smooth surface, and the active light-emitting pixel array is coupled with the active switch.

Optionally, the active switch and the active light-emitting pixel array are formed by the same manufacture procedure.

Optionally, the active switch and the active light-emitting pixel array are manufactured by an exposure machine with an exposure linewidth less than 1 μm.

This application further discloses a display panel including any of the aforementioned substrates.

Compared with the solution where there is not disposed a reflective layer on the substrate, the high energy laser emitted by a laser head irradiates the amorphous silicon base and crystallizes the amorphous silicon layer by means of high energy so that after a period of time the amorphous silicon layer would be converted into a polysilicon layer. In the process of converting the amorphous silicon layer into the polysilicon layer, the laser is partially absorbed by the amorphous silicon layer, while the rest of laser passes through the amorphous silicon layer to be indident on the reflective layer. The reflective layer has a smooth surface with a high reflectivity so that no diffuse reflection would occur, which ensures that the laser energy is not significantly compromised due to dispersion. As such, the laser is reflected by the reflective layer, and then again passes through the amorphous silicon layer. The amorphous silicon layer thus absorbs a part of the reflected laser to quickly form the polysilicon layer, thereby reducing the time required for laser crystallization. If the laser with the same energy is used to irradiate the amorphous silicon layer, then polysilicon coking, meaning that the energy is excessively high, may occur in the case where there is arranged the reflective layer on the base. Thus, the laser energy can be properly reduced to achieve the original effect without the reflective layer. Accordingly, the cycle of replacing consumables such as a laser head is favorably increased, and the time required for laser crystallization is reduced.

### BRIEF DESCRIPTION OF DRAWINGS

The accompanying drawings, which are included to provide a further understanding of embodiments of the present application and constitute a part of the specification, illustrate embodiments of the application and, together with the text description, explain the principles of the application. Apparently, the drawings in the following description are merely some embodiments of the present application, and those skilled in the art can obtain other drawings according to the drawings without any inventive efforts. A brief description the drawings is provided as follows.

FIG. 1 is a schematic block diagram of a display panel according to an embodiment of the present application.

FIG. 2 is a schematic diagram of a reflective layer and an active switch respectively disposed on two sides of a base according to an embodiment of the present application.

FIG. 3 is a cross-sectional view of a base according to an embodiment of the present application.

FIG. 4 is a schematic diagram of the structure in which a reflective layer and an active switch are disposed on the same side of the base according to an embodiment of the present application.

FIG. 5 is a flowchart of a method for manufacturing a substrate according to an embodiment of the present application.

FIG. 6 is a flowchart of a method for forming an active switch and an active light-emitting pixel array on a base according to an embodiment of the present application.

FIG. 7 is a flowchart of a method for converting an amorphous silicon layer into a polysilicon layer according to an embodiment of the present application.

### DETAILED DESCRIPTION OF EMBODIMENTS

It should be understood that the terminology used herein, and the various specific structural and functional details disclosed herein are merely exemplary for purposes of illustrating some specific embodiments. However, the present application may be practiced in many alternative forms and is not to be construed as being limited to the embodiments set forth herein.

As used herein, the terms “first” and “second” are intended for description purposes only and are not to be construed to indicate relative importance or imply the number of technical features as specified. Thus, unless otherwise specified, a feature defined as “first” and “second” may explicitly or implicitly include one or more of such feature; “multiple” and “a plurality of” mean two or more. The terms “include”, “comprise”, and any variations thereof are intended to be inclusive in a non-closed manner, that is, the presence or addition of one or more other features, integers, steps, operations, units, components, and/or combinations thereof may be possible.

In addition, the terms “center”, “horizontally”, “up”, “down”, “left” “right”, “vertical”, “horizontal”, “top”, “bottom”, “inner”, “outer” and the like for indicating an orientational or positional relationship are based on those depicted in the accompanying drawings, and they are intended for the mere purposes of simplying the description of the application, rather than indicating that the device or element referred to must have a particular orientation, or be configured and operated in a particular orientation. Thus, they are not to be construed as limiting the present application.

In addition, unless expressly specified and defined otherwise, the terms “mount”, “attach” and “connect” are to be understood in a broad manner. For example, it may be a fixed connection, a detachable connection, or an integral connection; it may either be an mechanical connection or an electrical connection; it may be a direct connection or an indirect connection achieved through an intermediate medium, or an internal connection between two elements. For those having ordinary skill in the art, the specific meanings of the above terms in this application can be understood depending on specific contexts.

The present application will now be described in further detail with reference made to the accompanying drawings and optional embodiments.

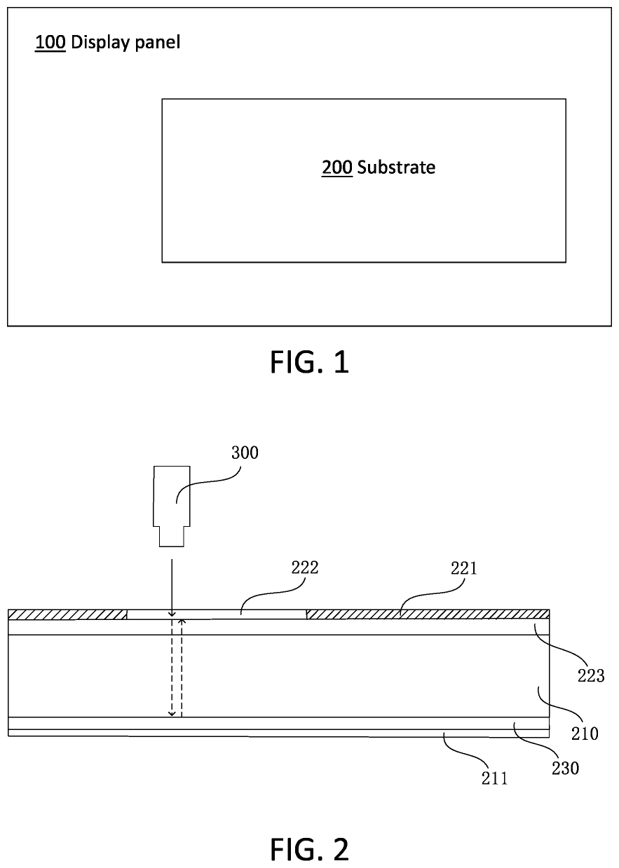

As illustrated in FIGS. 1 to 3, embodiments of the present application provide a display panel 100 that includes a substrate 200. The substrate 200 includes a base 210, an active switch 220, an active light-emitting pixel array 240. and a reflective layer 230. The active switch 220 is formed on the base 210. The reflective layer 230 is formed on the base 210 under the active switch 220 and is disposed farther away from the light incident surface of the substrate 200 compared with the active switch 220. The active light-emitting pixel array 240 is coupled with the active switch 220. The active switch 220 includes a polysilicon layer 222. The reflective layer 230 totally covers the base 210, and has a smooth surface.

The polysilicon preparation apparatus includes a laser head 300 and a support table. A high-energy laser emitted by the laser head 300 irradiates the amorphous silicon base 210 and crystallizes the amorphous silicon layer 211 by virtue of the high energy so that the amorphous silicon layer 221 is converted into a polysilicon layer 222 after a certain period of time. In the process of converting the amorphous silicon layer 221 into the polysilicon layer 222, a part of the laser is absorbed by the amorphous silicon layer 221, while the rest of laser passes through the amorphous silicon layer 221 and irradiates the reflective layer 230. The surface of the reflective layer 230 is smooth with a high reflectivity so that no diffuse reflection will occur, which ensures that the laser energy is not significantly compromised due to dispersion. The projection of the reflective layer 230 on the base 210 totally covers the amorphous silicon layer 221, ensuring that the laser reflected by the reflective layer 230 covers all the amorphous silicon layer 221 before being reflected by the reflective layer 230 and then again passing through the amorphous silicon layer 221. The amorphous silicon layer 221 absorbs a part of the reflected laser thus quickly forming the polysilicon layer 222, thereby reducing the time required for laser crystallization. If the laser with the same energy is used to irradidate the amorphous silicon layer 221, then polysilicon coking, meaning that the energy is excessively high, may occur in the case where there is disposed the reflective layer 230 on the base 210. Thus, the laser energy can be properly reduced to achieve the original effect without the reflective layer 230. Accordingly, the cycle of replacing consumables such as the laser head 300 is favorably increased. The active switch 220 includes a first cushion layer 223 disposed on the base 210, and the polysilicon layer 222 is disposed on the first cushion layer 223. The base 210 usually contains impurities. If the polysilicon layer 222 is disposed on the base 210, then after the amorphous silicon layer 221 is converted into the polysilicon layer 222, the impurities in the base 210 may diffuse into the polysilicon layer 222, causing electrical abnormality of the display device. In view of this, the first cushion layer 223 is disposed to block the impurities from entering the polysilicon layer 222.

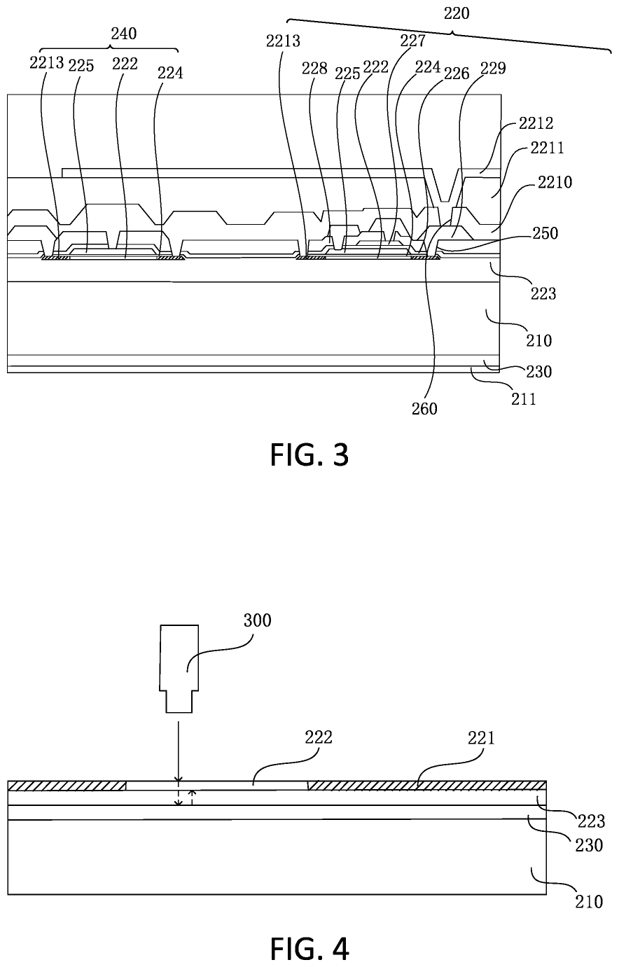

As illustrated shown in FIG. 3, the active switch 220 includes a conductive layer 2213, a second cushion layer 224, a first metal layer 225, a first insulating layer 226, a second metal layer 227, a second insulating layer 228, and a third metal layer 229. The substrate 200 includes a third insulating layer 2210 covering the third metal layer 229, a flattening layer 2211, and a transparent conductive film 2212. The second cushion layer 224, the first metal layer 225, the first insulating layer 226, the second metal layer 227, the second insulating layer 228, the third metal layer 229, the third insulating layer 2210, the flattening layer 2211, and the transparent conductive film 2212 are sequentially laid on the amorphous silicon layer 221. The third metal layer 229 is coupled with the conductive layer 2213 through a first via hole 250, and the transparent conductive film 2212 is coupled with the third metal layer 229 through a second via hole 260. The transparent conductive film 2212 covers the active switch 220 and the active light-emitting pixel array 240 in a direction perpendicular to the base 210.

The second cushion layer 224 may serve the same function of isolating impurities as the first cushion layer 223, in order to prevent the first metal layer 225 from being conducted with the amorphous silicon layer 221. The first cushion layer 223 and the second cushion layer 224 are made of the same material, which may be silicon dioxide, to prevent impurities within the base 210 or the first metal layer 225 from diffusing into the polysilicon layer 222 thus affecting the conductive property of polysilicon and causing electrical abnormality of the display device. The first insulating layer 226, the second insulating layer 228, and the third insulating layer 2210 all have an insulating effect, respectively isolating the first metal layer 225 from the second metal layer 227. the second metal layer 227 from the third metal layer 229, and the third insulating layer 2210 from the transparent conductive film 2212. The flattening layer 2211 serves to make the transparent conductive film 2212 laid on the flattening layer 2211 more fiat and uniform, so as to avoid unevenness of the laid transparent conductive film 2212. The base 210 includes an active light-emitting pixel array 240 that is disposed on the base 210 and coupled to the active switch 220. After the polysilicon layer 222, the conductive layer 2213, the first metal layer 225, the second metal layer 227, and the third metal layer 229 are produced, they may be etched to form a predetermined pattern, becoming a film layer having a specific pattern. The conductive layer 2213 is etched to form the source electrodes and drain electrodes of the active switch 220 and the active light-emitting pixel array 240. The source electrode and drain electrode of the active switch 220 are respectively disposed at two sides of the polysilicon layer 222 of the active switch 220 and coupled with the polysilicon layer 222. The source electrode and drain electrode of the active light-emitting pixel array 240 are respectively disposed at two sides of the polysilicon layer 222 of the active light-emitting pixel array 240 and coupled to the polysilicon layer 222. The conductive layer 2213 has good conductivity, and may be made of metal or other conductive materials. The first insulating layer 226, the second insulating layer 228, the third insulating layer 2210, the second cushion layer 224, and the flattening layer 2211 are each provided with a via hole for communicating the upper and lower layers. The active switch 220 may be a driver thin film transistor (TFT), and the active light-emitting pixel array 240 may be a switching TFT. The driver TFT is used for providing a voltage for the switching TFT, turning on or off the switching TFT for light emission. Since the switching TFT is a single-sided, for example, organic light-emitting diode ((SLED) that emits light in one direction, and requires no backlight, the reflective layer 230 of the base 210 would not interfere with the light emission of the display panel 100.

In addition, the base 210 may be made of glass or plastic material, and may have a circular shape. Such polysilicon manufacturing apparatus is mainly used for producing products of high resolution with a pixel density over 3000, such as a head-mounted virtual real (VR) device. Due to the exposure wavelength and platform capacity, the minimum linewidth of an exposure machine used by the panel is about 2-3 μm. However, the required exposure linewidth for a pixel density over 3000 is usually less than 1 μm, and thus a high-precision exposure machine in a chip process is needed. The chip process adopts a circular base 210, but the base 210 in the present application is not limited to a circular shape, and can be form into a square shape by means of cutting. Infrared rays irradiate the reflective layer 230 on the base 210 and are reflected to an infrared ray receiver, and the exposure platform determines the position and the condition of the base 210 by through the infrared ray receiver.

The reflective layer 230 and the active switch 220 are respectively disposed on two sides of the base 210; that is, the reflective layer 230 is disposed on one side of the base 210 disposed farther away from the active switch 220. The substrate 200 includes a protective layer 211 disposed on and cladded to the reflective layer 230. The reflective layer 230 is disposed under the base 210, and a protective layer 211 is disposed on the reflective layer 230 to prevent scratching, thus preventing the metallic Al reflective layer 230 on the back of the base 210 from being scratched which may otherwise produce particles during the tape-out process of the base 210. The protective layer 211 may be made of SiO₂. As illustrated in FIG. 4, the reflective layer 230 may alternatively be displosed on the same side as the amorphous silicon layer 221; that is, the reflective layer 230 and the active switch 220 are both displosed on one side of the base 210. The active switch 220 includes a first cushion layer 223 disposed on the reflective layer 230, and the amorphous silicon layer 221 is disposed on the first cushion layer 223. This eliminates the need to reverse the base 210 to form the reflective layer 230 on the other side, and the need to form the protective layer 211 on the Al reflective layer 230, making it time- and labor-efficient.

The reflective layer 230 may be made of aluminum, or may be other flat metal reflective surfaces. Aluminum has high reflectivity. Generally, the bottom surface of the plane mirror is coated with an aluminum layer and a silver layer, both having good reflectivity, but aluminum is less expensive than silver. The reflective effect of the reflective layer 230 is not diffuse, since the conversion of amorphous silicon into polysilicon requires high energy. The reflective properties of the material of the reflective layer 230 cannot be diffuse, i.e., the surface of the reflective layer 230 cannot be coarse or rough, since when a parallel incident light beam is irradiated to a rough reflective layer 230, the coarse surface reflects the light beam in all directions, causing irregular reflection of the reflected light. For example, diffuse reflection by a mirror, a concave lens and the like, may disperse the energy of the laser beam, such that the reflected laser energy is insufficient to convert the amorphous silicon into polysilicon, the processing time will not be shortened, and the polysilicon conversion efficiency cannot be improved.

The present application is particularly suitable for a single-sided self-luminous display panel, such as an OLED panel. Therefore, the reflective layer can totally cover the base, and the utilization of light energy is improved to the maximum extent.

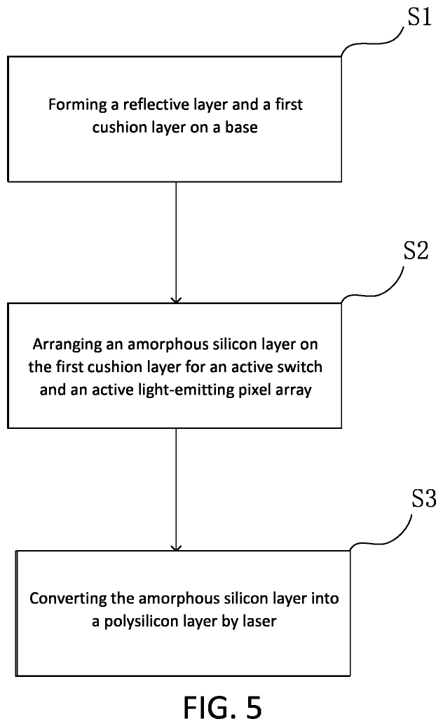

As illustrated in FIG. 5, referring also to FIGS. 2 and 4, the present application further discloses a method of manufacturing a substrate, the method including the following operations:

S1: forming a reflective layer and a first cushion layer on a base;

S2: arranging an amorphous silicon layer on the first cushion layer for an active switch and an active light-emitting pixel array; and

S3: converting the amorphous silicon layer 221 into a polysilicon layer by laser;

where the reflective layer 230 is formed on the base 210 under the active switch and is disposed farther away from the light incident surface of the substrate compared with the active switch; the reflective layer 230 totally covers the base 210, the surface of the reflective layer 230 is smooth, and the active light-emitting pixel array is coupled with the active switch.

The position of the reflective layer 230 may have two cases. One is that the reflective layer 230 is disposed on one side of the base 210 disposed farther away from the active switch. The reflective layer 230 and the active switch are respectively disposed on the upper side and the lower side of the base 210. As the reflective layer 230 has a smaller number of layers and a relatively higher flatness compared with the active switch, the reflective layer 230 and the protective layer 211 are disposed first, and then the base 210 will not be inclined due to unevenness of the reflective layer 230 at the bottom when the base 210 is inverted for forming the active switch, so that the manufacture and precision of the active switch are not affected. After the amorphous silicon layer 221 is converted into the polysilicon layer 222, the existence of the reflective layer 230 and the protective layer 211 does not interfere with the normal operation of the active switch, but may increase the thickness of the base 210. The reflective layer 230 and the protective layer 211 can be removed by etching, the base 210 can be inverted, and the SiO₂ protective layer 211 and the Al reflective layer 230 can be removed by dry etching. In another case, the reflective layer 230 is disposed on the side of the base 210 close to the active switch, that is, the reflective layer 230 and the active switch are disposed on the same side of the base 210, and the active switch is disposed on the reflective layer 230 without inverting the base 210. Thus the manufacture procedure for the protective layer 211 on the reflective layer 230 is spared, thus improving the time- and labor-efficiency.

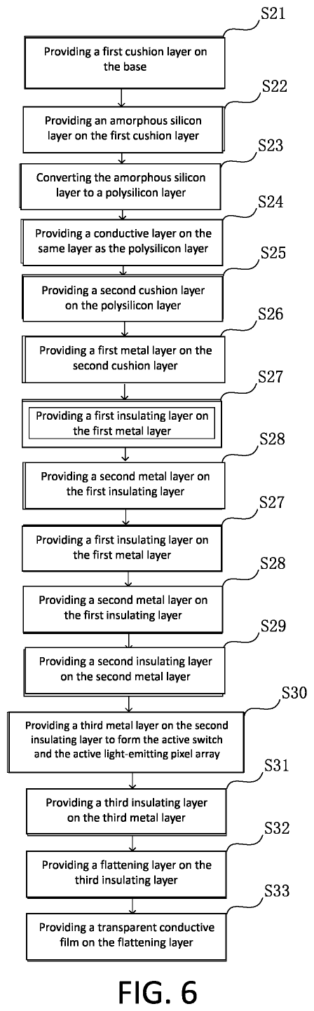

As illustrated in FIG. 6, the operation of forming the active switch and the active light-emitting pixel array on the base may include the following operations:

S21: providing a first cushion layer on the base;

S22: providing an amorphous silicon layer on the first cushion layer;

S23: converting the amorphous silicon layer into a polysilicon layer;

S24: providing a conductive layer on the same layer as the polysilicon layer;

S25: providing a second cushion layer on the polysilicon layer;

S26: providing a first metal layer on the second cushion layer;

S27: providing a first insulating layer on the first metal layer;

S28: providing a second, metal layer on the first insulating layer;

S29: providing a second insulating layer on the second metal layer;

S30: providing a third metal layer on the second insulating layer to form the active switch and the active light-emitting pixel array;

S31: providing a third insulating layer on the third metal layer;

S32: providing a flattening layer on the third insulating layer; and

S33: providing a transparent conductive film on the flattening layer;

In the above process, the polysilicon layer, the conductive layer, the first metal layer, the second metal layer and the third metal layer are etched to form predetermined patterns, and the overlapping, areas between the second insulating layer and the third insulating layer, and the transparent conductive film and the third metal, layer of the active switch are provided with a via hole. The polysilicon layer is coupled with the conductive layer. The transparent conductive film is coupled with a third metal layer of the active switch through a second via hole, and the third metal layer of the active switch is coupled with the conductive layer of the active switch. The first cushion layer, polysilicon layer, conductive layer, second cushion layer, first metal layer, first insulating layer, second metal layer, third insulating layer, flattening layer, and transparent conductive film are sequentially disposed on the base. The active switch and the active light-emitting pixel array are formed using the same manufacture procedure. When forming the active switch and the active light-emitting pixel array, the coating photoresist of the polysilicon layer, the conductive layer, the first metal layer, second metal layer, third metal layer and the like requires photomask, etching and peeling off to form the predetermined pattern and active switches and active light-emitting, pixel arrays of different structures. The precision of exposure linewidth for photomask is less than 1 μm, and the exposure machine used for chip technology is adopted. For example, an amorphous silicon layer is laid on the first cushion layer; photoresist is applied to the amorphous silicon layer; a predetermined pattern is formed through exposure and development; the photoresist is removed except for the predetermined pattern by a peeling reagent; the amorphous silicon outside the pattern is removed by an etching reagent to form an amorphous silicon layer with a specific pattern. By etching the amorphous silicon layer before the amorphous silicon layer is converted into the polysilicon layer, unnecessary amorphous silicon section is not converted, thereby improving the conversion efficiency, lengthening the cycle of replacement of the laser device consumables, and shortening the time required for laser crystallization.

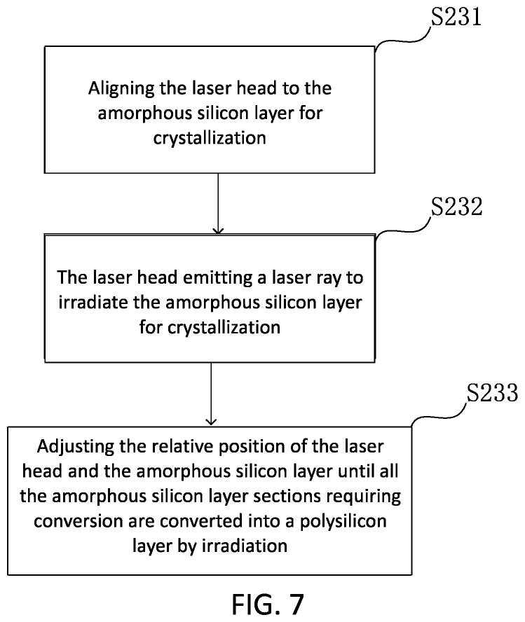

As illustrated in FIG. 7, the operation of converting the amorphous silicon layer into the polysilicon layer may include:

S231: aligning the laser head to the amorphous silicon layer for crystallization;

S232: the laser head emitting a laser ray to irradiate the amorphous silicon layer for crystallization; and

S233: adjusting the relative position of the laser head and the amorphous silicon layer until all the amorphous silicon layer sections requiring conversion are converted into a polysilicon layer by irradiation.

Since the cross section area of laser emitted by the laser head is generally smaller than the surface area of the amorphous silicon layer, the laser cannot totally cover the amorphous silicon layer. As such, the relative position of the laser head to the base requires adjustment after a part of the amorphous silicon layer is converted into the polysilicon layer until all the amorphous silicon layer sections requiring conversion are converted into the polysilicon layer.

It should be noted that, as long as the implementation of the specific solution is not affected, the execution of the solution will not be limited to the order as described above. In particular, the operations written earlier may be performed earlier or later than, or even simultaneously with those written latter. Any solution, if it is possible to be implemented, shall all be deemed as falling in the scope of protection of the present application.

The foregoing merely provides a detailed description of the present application in connection with some specific optional embodiments, but the present application will not be limited to these specific embodiments as set forth herein. For those having ordinary skill in the art to which this application pertains, numerous straightforward derivations or substitutions may be made without departing from the spirit of this application, and all of these derivations or substitutions shall be regarded as falling the scope of protection of this application.

What is claimed is:

1. A substrate, comprising:
a base;
an active switch, formed on the base and comprising a polysilicon layer;
an active light-emitting pixel array, coupled with the active switch; and
a reflective layer, which is formed on the base under the active switch and which is disposed farther away from a light incident surface of the substrate than the active switch;
wherein the reflective layer fully covers the base and comprises a smooth surface.

2. The substrate of claim 1, wherein the active switch comprises a first cushion layer disposed on the base, and wherein the polysilicon layer is disposed on the first cushion layer.

3. The substrate of claim 1, wherein the reflective layer and the active switch are respectively disposed on two sides of the base, and wherein the base comprises a protective layer that is disposed on and cladded to the reflective layer.

4. The substrate of claim 1, wherein the reflective layer and the active switch are disposed on a same side of the base, wherein the active switch comprises a first cushion layer disposed on the reflective layer, and wherein the polysilicon layer is disposed on the first cushion layer.

5. The substrate of claim 2, wherein the active switch comprises a conductive layer, a second cushion layer, a first metal layer, a first insulating layer, a second metal layer, a second insulating layer, and a third metal layer;
wherein the substrate comprises a third insulating layer covering the third metal layer, a flattening layer, and a transparent conductive film, and wherein the second cushion layer, the first metal layer, the first insulating layer, the second metal layer, the second insulating layer, the third metal layer, the third insulating layer, the flattening layer, and the transparent conductive film are sequentially laid on the polysilicon layer; and
wherein the third metal layer is coupled with the conductive layer through a first via hole, and the transparent conductive film is coupled with the third metal layer through a second via hole.

6. The substrate of claim 1, wherein the reflective layer is made of aluminum.

7. The substrate of claim 5, wherein the transparent conductive film covers the active switch and the active light-emitting pixel array in a direction perpendicular to the base.

8. The substrate of claim 5, wherein the first cushion layer and the second cushion layer are made of a same material.

9. The substrate of claim 8, wherein the first cushion layer and the second cushion layer are both made of silicon dioxide.

10. The substrate of claim 7, wherein the conductive layer is etched to form a source electrode and a drain electrode of the active switch and those of the active pixel array, wherein the source electrode and drain electrode of the active switch are respectively disposed on two sides of the polysilicon layer of the active switch and are coupled with the polysilicon layer, and the source electrode and drain electrode of the active light-emitting pixel array are respectively disposed on two sides of the polysilicon layer of the active light-emitting pixel array and are coupled with the polysilicon layer.

11. The substrate of claim 1, wherein the base has a circular shape.

12. A method of manufacturing a substrate, comprising:
forming a reflective layer on a base;
arranging an amorphous silicon layer on the reflective layer for an active switch and an active light-emitting pixel array; and
converting the amorphous silicon layer into a polysilicon layer by laser;
wherein the reflective layer is arranged to fully cover the base and comprises a smooth surface, and wherein the active light-emitting pixel array is coupled with the active switch.

13. The method of claim 12, wherein the active switch and the active light-emitting pixel array are formed by a same manufacture procedure.

14. The method of claim 12, wherein the active switch and the active light-emitting pixel array are formed using an exposure machine with an exposure linewidth less than 1 μm.

15. The method of claim 12, wherein the reflective layer and the active switch are disposed on a same side of the base, wherein the active switch comprises a first cushion layer disposed on the reflective layer, the polysilicon layer is disposed on the first cushion layer, and the reflective layer is made of aluminum.

16. The method of claim 12, further comprising an operation of determining a position of the base, the operation comprising:
irradiating an infrared ray to the reflective layer by an exposure machine;
receiving an reflected infrared ray by an infrared ray receiver; and
determining the position of the base according to information of the received infrared ray by the infrared receiver.

17. A display panel comprising, a substrate, the substrate comprising:
a base;
an active switch, formed on the base and comprising a polysilicon layer;
an active light-emitting pixel array, coupled with the active switch; and
a reflective layer, which is formed on the base at the bottom of the active switch and which is disposed farther away from a light incident surface of the substrate than the active switch;
wherein the reflective layer fully covers the base and comprises a smooth surface.

18. The display panel of claim 17, wherein the active switch comprises a first cushion layer disposed on the base, and wherein the polysilicon layer is disposed on the first cushion layer;
the active switch further comprises a conductive layer, a second cushion layer, a first metal layer, a first insulating layer, a second metal layer, a second insulating layer, and a third metal layer;
wherein the substrate comprises a third insulating layer covering the third metal layer, a flattening layer, and a transparent conductive film, and wherein the second cushion layer, the first metal layer, the first insulating layer, the second metal layer, the second insulating layer, the third metal layer, the third insulating layer, the flattening layer and the transparent conductive film are sequentially laid on the polysilicon layer; and
wherein the third metal layer is coupled with the conductive layer through a first via hole, and the transparent conductive film is coupled with the third metal layer through a second via hole; and
the transparent conductive film covers the active switch and the active light-emitting pixel array in a direction perpendicular to the base.

19. The display panel of claim 17, wherein the display panel is a single-sided self-luminous display panel.
